(19) United States
(12) Patent Application Publication
(10) Pub. No.: US 2025/0380500 A1
(43) Pub. Date: Dec. 11, 2025

(54) ROBUST HALFBRIDGE

(71) Applicant: VISIC TECHNOLOGIES LTD., Ness Ziona (IL)

(72) Inventors: Valery Veprinsky, Tel Aviv (IL); Yulia Roiter, Tel Aviv (IL); Daniel Sherman, Ness Ziona (IL)

(21) Appl. No.: 18/865,346

(22) PCT Filed: May 18, 2023
(86) PCT No.: PCT/IL2023/050513

§ 371 Date: Nov. 13, 2024

Related U.S. Application Data
(60) Provisional application No. 63/343,348, filed on May 18, 2022.

(51) Int. Cl. H10D 84/83; H03K 17/687; H10D 64/23; H10D 64/27

(52) U.S. Cl. CPC H10D 84/835; H03K 17/6871; H10D 64/257; H10D 64/519; H03K 2217/0072

(57) ABSTRACT

A semiconductor transistor comprising: a drain region; a plurality of source regions; and a plurality of gate regions interleaved with the source regions.

### RELATED APPLICATION

This application claims benefit under 35 U.S.C. 119(e) of U.S. Provisional Application 63/343,348 filed May 18, 2022, the disclosures of which are incorporated herein by reference.

### FIELD

Embodiments of the invention relate to providing a half bridge circuit having improved resistance to shoot-through.

### BACKGROUND

A common element of many circuits, in particular high power conversion circuits, is a half H-bridge, or a half bridge. A half bridge comprises first and second switches, generally MOSFET transistors, connected in series at a junction that functions as an output node of the half bridge.

In operation the first MOSFET transistor, conventionally referred to as a high side (HS) transistor or switch, is connected to a high voltage terminal of a power source, and the second MOSFET transistor, conventionally referred to as a low side (LS) transistor or switch, is connected to a low voltage terminal of the power source. Dedicated, HS and LS, gate drivers are respectively connected to the gates of the HS and LS transistors and control the transistors to be ON (closed) and conducting, or OFF (open) and non-conducting. A load is connected between the output node of the half bridge and the low voltage terminal of the power source. When the HS gate driver controls the HS transistor to be ON and the LS driver controls the LS transistor to be OFF, the half bridge output node rises to the voltage, “V_{HS}”, of the high voltage terminal, the half bridge may be said to be ON, the load is connected to the HS terminal of the power supply and the power supply provides current and power to the load. When the gate drivers control the HS transistor to be OFF and the LS transistor to be ON, the half bridge node falls to the voltage, “V_{LS}”, of the low voltage terminal of the power source, the half bridge may be said to be OFF, and the power source ceases to provide current and power to the load. To prevent a shoot-through rush of current through the half bridge that shorts and may damage the power source and/or an element of a circuit that comprises the power source, the HS and LS gate drivers are controlled in synchrony so that when one of the transistors is ON the other is OFF.

Since switching times of the HS and LS transistors are invariably subject to jitter, to aid in protecting the power supply from shorting, before switching between ON and OFF states of the half bridge the gate drives are synchronized to control both transistors to be OFF for a short period of time, referred to as a dead-time period or simply dead-time. However, even when protected by dead time hiatuses, when switching between a dead-time and an ON state of a half bridge a voltage surge at the half bridge LS transistor may produce a voltage at the LS transistor gate that turns the LS transistor ON while the HS transistor is ON and generates a shoot-through of the half bridge.

### SUMMARY

An aspect of an embodiment of the disclosure relates to providing a half bridge having improved immunity to shoot-through. To provide the enhanced immunity, in accordance with an embodiment of the disclosure, the LS transistor is formed having a plurality of source regions interleaved with gate regions operable to control current to a same drain region. When the source regions are electrically connected in parallel to form a compound source, and the gate regions are electrically connected in parallel to form a compound gate, the interleaved source regions and gate regions endow the LS transistor with a relatively large, built-in gate-source capacitance connected by relatively low impedance current channels between the compound gate and the compound source. The large, built-in capacitance operates to moderate voltage swings between the gate and source and reduce a probability of shoot-through when the half bridge is switched from dead-time to ON.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE FIGURES

Non-limiting examples of embodiments of the invention are described below with reference to figures attached hereto that are listed following this paragraph. Identical structures, elements or parts that appear in more than one figure are generally labeled with a same numeral in all the figures in which they appear. A label labeling an icon representing a given feature in a figure of an embodiment of the disclosure may be used to reference the given feature Dimensions of components and features shown in the figures are chosen for convenience and clarity of presentation and are not necessarily shown to scale.

FIG. 1 schematically shows a half bridge, in accordance with prior art;

FIG. 2A-FIG. 2D schematically illustrate operation of the half bridge shown in FIG. 1 when cycling between ON and OFF states interleaved with dead-times, in accordance with prior art;

FIG. 3A schematically shows an enlarged image of the half bridge shown in FIG. 2A after switching from a dead-time state to an ON state, in accordance with prior art;

FIG. 3B schematically shows the half bridge as shown in FIG. 3A comprising a shunt capacitor to reduce a probability of shoot-through, in accordance with prior art;

FIG. 4 schematically shows the half bridge as shown in FIG. 3A comprising a low side transistor having a relatively large built-in capacitance to reduce a probability of shoot-through, in accordance with an embodiment of the disclosure;

FIGS. 5A-5B schematically illustrate changes made to construction of a LS transistor optionally for use in a half bridge to reduce a probability of shoot-through, in accordance with an embodiment of the disclosure;

FIGS. 6A-6B schematically show transistors having a source region and a gate region that completely surround a drain region of the transistor, in accordance with an embodiment of the disclosure; and

FIGS. 7A-7D schematically show transistor switching dies comprising a plurality of transistors, in accordance with an embodiment of the disclosure.

### DETAILED DESCRIPTION

In the discussion, unless otherwise stated, adjectives such as “substantially” and “about” modifying a condition or relationship characteristic of a feature or features of an embodiment of the disclosure, are understood to mean that the condition or characteristic is defined to within tolerances that are acceptable for operation of the embodiment in an application for which it is intended. Wherever a general term in the disclosure is illustrated by reference to an example instance or a list of example instances, the instance or instances referred to, are by way of non-limiting example instances of the general term, and the general term is not intended to be limited to the specific example instance or instances referred to. The phrase “in an embodiment”, whether or not associated with a permissive, such as “may”, “optionally”, or “by way of example”, is used to introduce for consideration an example, but not necessarily required, configuration of possible embodiments of the disclosure. Each of the verbs, “comprise” “include” and “have”, and conjugates thereof, are used to indicate that the object or objects of the verb are not necessarily a complete listing of components, elements or parts of the subject or subjects of the verb. Unless otherwise indicated, the word “or” in the description and claims is considered to be the inclusive “or” rather than the exclusive or, and indicates at least one of, or any combination of more than one of items it conjoins.

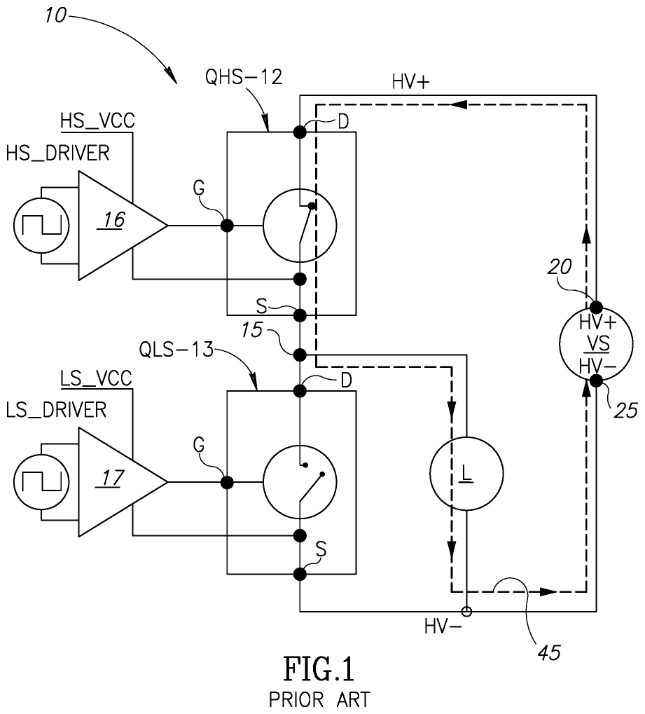

FIG. 1 schematically shows a half bridge 10 in accordance with prior art that is common to many conversion circuits. Half bridge 10 includes a high side switch QHS-12 and a low side switch QLS-13, generally MOSFET transistors, connected in series at a junction 15 that functions as an output node of half bridge 10. Each transistor has a source S, a drain D and a gate G. A high side gate driver HS_DRIVER 16 is connected between gate G and source S of transistor QHS-12 and controls a voltage difference between the source and the gate to control QHS-12 to be ON (closed) and conducting, or OFF (open) and non-conducting. Similarly, a low side gate driver LS_DRIVER 17 is connected between source S and a gate G of low side transistor QLS-13 and controls the low side transistor to be ON or OFF. In the figure, half bridge 10 is shown connected to a load L and to a high voltage terminal 20 of a high voltage power source VS, that provides a voltage HV+ at a high voltage terminal 20 and a voltage HV− at a low voltage terminal 25. By way of example, transistors QHS-12 and QLS-13 are assumed to be n-channel transistors and drain D of transistor QHS-12 is connected to high voltage terminal 20, that provides voltage HV+ and source S of transistor QLS-13 is connected to low voltage terminal 25 that provides voltage HV−. Load L is connected between output node 15 of half bridge 10 and low voltage terminal 25 of power source VS.

FIG. 1 shows half bridge 10 ON with high side gate driver HS-16 controlling transistor QHS-12 to be ON (switch closed) and low side driver LS-17 controlling transistor QLS-13 to be OFF (switch open). As a result of half bridge 10 being ON, output node 15 is set to voltage HV+ provided by terminal 20, and power supply VS drives a current represented by a dashed arrowed line 45 through load L.

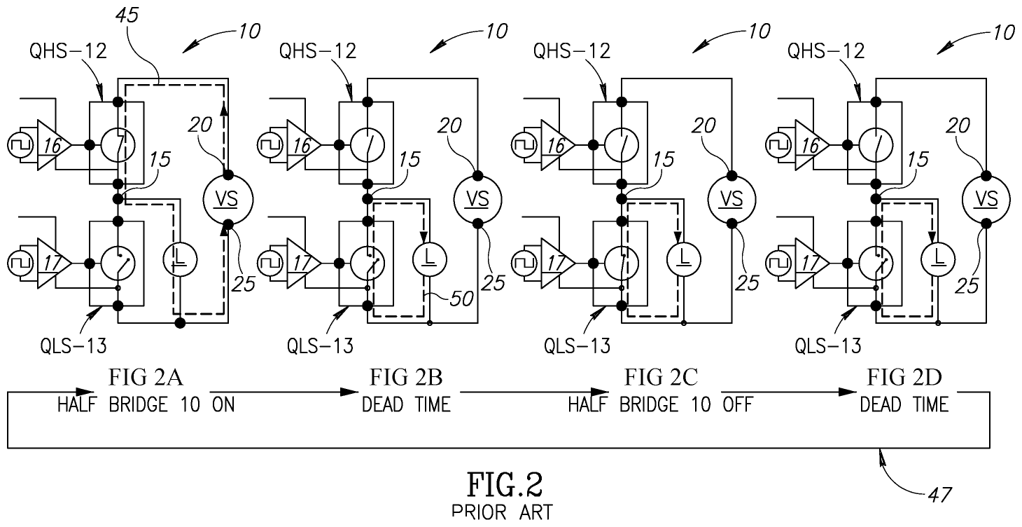

FIGS. 2A through 2D schematically show HS-Driver 16 and LS-Driver 17 controlling transistors QHS-12 and QLS-13 to turn ON and turn OFF half bridge 10 through a conventional sequence of ON and OFF states of the half bridge interspersed with dead-time periods to alternately connect and disconnect load L to voltage HV+ and provide power to load L with pulses of current. A timeline 47 along the bottom of FIG. 2A shows half bridge 10 ON and driving current 45 through load L as depicted also in FIG. 1. FIG. 2B shows half bridge 10 in a dead-time period with both QHS-12 and QLS-12 OFF following the ON state of half bridge 10 shown in FIG. 2A. When switched to the dead-time a transient decaying current represented by a dashed line 50 supported by parasitic inductance and capacitance flows for a limited time period through load L. FIG. 2C schematically shows the half bridge turned OFF with gate drivers 16 and 17 respectively controlling transistor QHS-12 to be OFF and transistor QLS-13 to be ON, followed by the dead time shown in FIG. 2D. In the OFF state, half bridge node 15 falls to low voltage HV− of terminal 25 of power source VS, there is no voltage drop across load L, and power source VS ceases to provide current and power to the load.

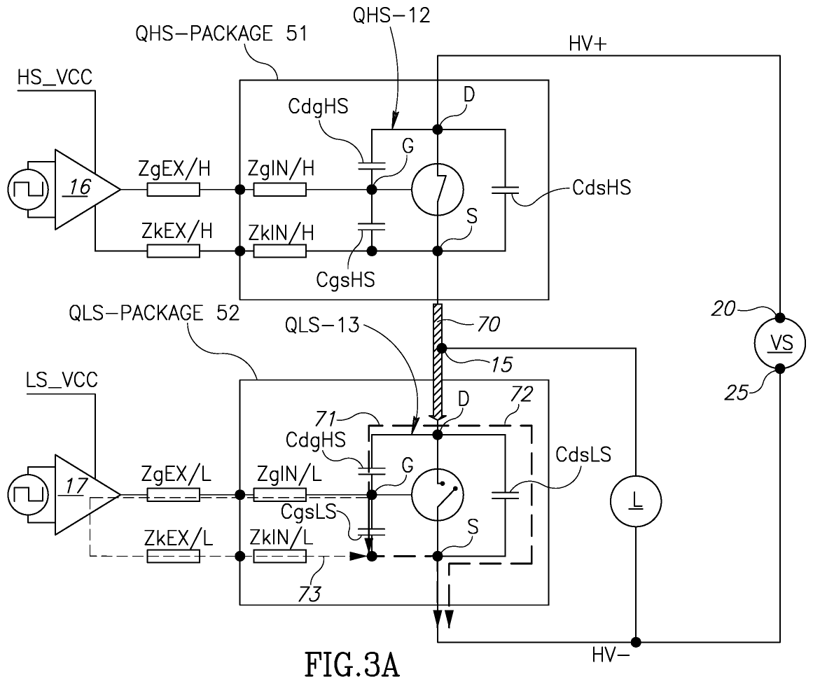

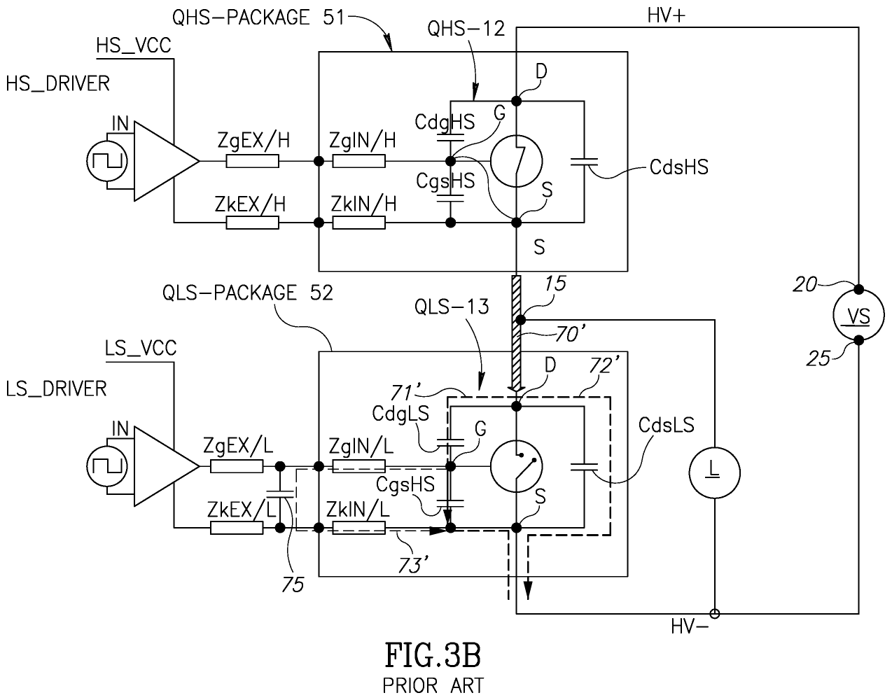

FIG. 3A schematically shows details of half bridge 10 that are relevant to operation of the half bridge and illustrates behavior of the half bridge that may generate damaging current shoot-through and ringing of volage applied to load L when the half bridge is switched from a dead-time (FIG. 2D) to ON (FIG. 2A).

Transistor QHS-12 is characterized by parasitic capacitances CdgHS, CgsHS and CdsHS and is comprised in a QHS-package-51 having internal impedances ZgIN/H and ZkIN/H through which electrical connections may be made from outside the die to gate G and source S respectively of the transistor. HS-driver 16 is connected to gate G and source S of transistor QHS-12 via impedances ZgEx/H and ZkEx/H respectively that are external to QHS-package-51. ZgEx/H and ZkEx/H are generally characteristic of conductive traces that connect the HS-driver and transistor QHS-12 on a printed circuit board (PCB) to which the HS-driver and transistor QHS-12 are mounted. Similarly, transistor QLS-13 is characterized by parasitic capacitances CdgLS, CgsLS and CdsLS and is comprised in a QLS-package-52 having internal impedances ZgIN/L and ZkIN/L through which electrical connections may be made to gate G and source S respectively of transistor QLS-13. LS-driver 17 is connected to transistor QLS-13 via ZgEx/L and ZkEx/L that are external to QLS-package-51.

When turning ON transistor QHS-12 to switch between a dead-time (FIG. 2D) of half bridge 10 and an ON state (FIG. 2A) of the half bridge, a transient current represented by a block arrow 70 flows from power source VS via transistor QHS-12 to QLS-13. Transient current 70 splits to transient currents represented by dashed lines 71 and 72 that charge parasitic capacitances CdgLS, CgsLS and CdsLS of transistor QLS-13 and flow on towards low voltage terminal 25 of power source VS. A portion 73 of current 71 flows through impedances ZgIN/L, ZgEx/L, ZkEx/L, and ZkIN/L to power source VS. Voltage to which transient current 70 and its transient tributary currents 71, 72, and 73 raise parasitic capacitor CgsLS, produces a voltage at gate G of QLS-13 that provides a voltage difference between gate G and source S of transistor QLS-12, that operates to turn ON the transistor and cause a possibly damaging shoot-through current.

Prior art attempts to prevent shoot-through and/or moderate ringing at output node 15 generally comprises providing transistor QLS-13 with, as schemtically shown in FIG. 3B, a capacitor 75 in parallel with parasitic capacitance CgsLS. As a result of structural constraints capacitor 75 is mounted outside of QLS-package-52 and operates as a low impedance, that shunts external impedances ZgEX/L and ZkEx/L. When swtiching between dead-time and ON, transient currents 70′, 71′ and 72′ and 73′ are generated, but as schematically indicted in FIG. 3B substantially no curent flows through ZgEX/L and ZkEx/L. Capacitor 75 reduces the overall impedance between gate G and source S of QLS-13 to about that created by impedances inside QLS-package 52 in parallel with capacitor 75. The reduced impedance advantageously limits voltage generated between gate G and source S of transistor QLS-13 when half bridge 10 is switched from a dead-time to an ON state.

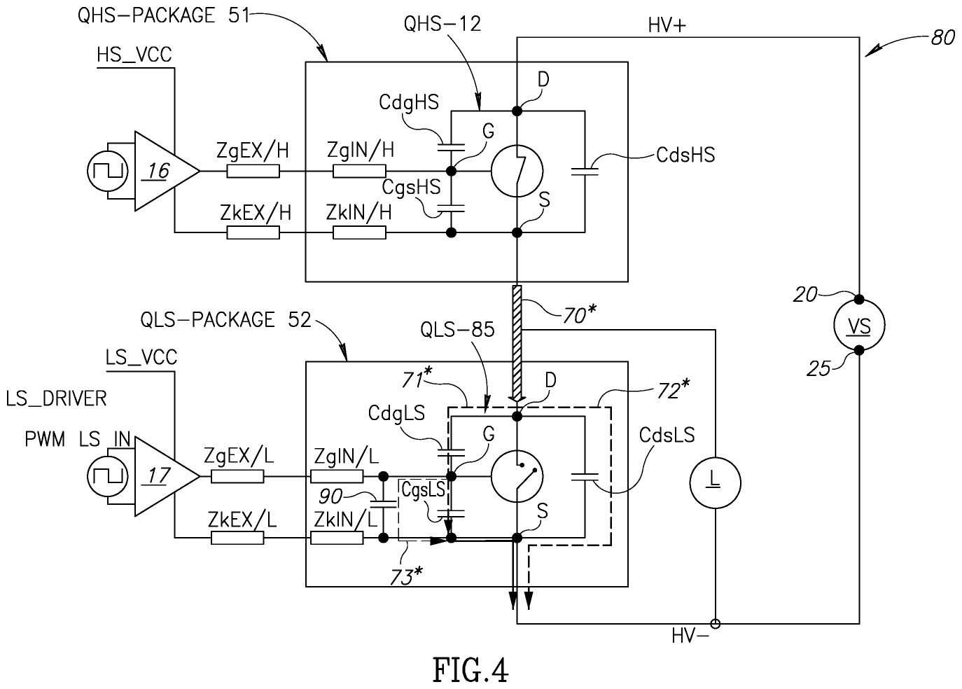

FIG. 4 schematically illustrates a half bridge 80 configured to exhibit relatively robust immunity to shoot-through, in accordance with an embodiment of the disclosure. Half bridge 80 comprises a transitor QLS-85 having a “built-in” capacitor 90 that shunts not only external impedances ZgEX/L and ZkEx/L but also internal impedances ZgIN/L and ZkIN/L of QLS package 52. When switching between dead-time and ON transient currents, 70*, 71* and 72* and 73* are generated, but as schematically indicted in FIG. 4 substantially no transient current flows through the impedance series ZgIN/L, ZgEx/L, ZkEx/L, and ZkIN/L. Internal capacitor 90 increases the ratio CgsLS/CgdLS and reduces impedance between gate G and source S of transitor QLS-85 to substantially the impedance of capcitor 90 in parallel with parasitic impedance CgsLS. The increased ratio CgsLS/CgdLS and reduced impedance advantageously limits voltage generated between gate G and source S of transistor QLS-85 when half bridge 10 is switched from a dead-time to an ON state to a voltage substantially less than that provided by the prior art configuration shown in FIG. 3B. The integrated internal capacitor CgsLS also enables faster switching and therefore higher overall efficiency.

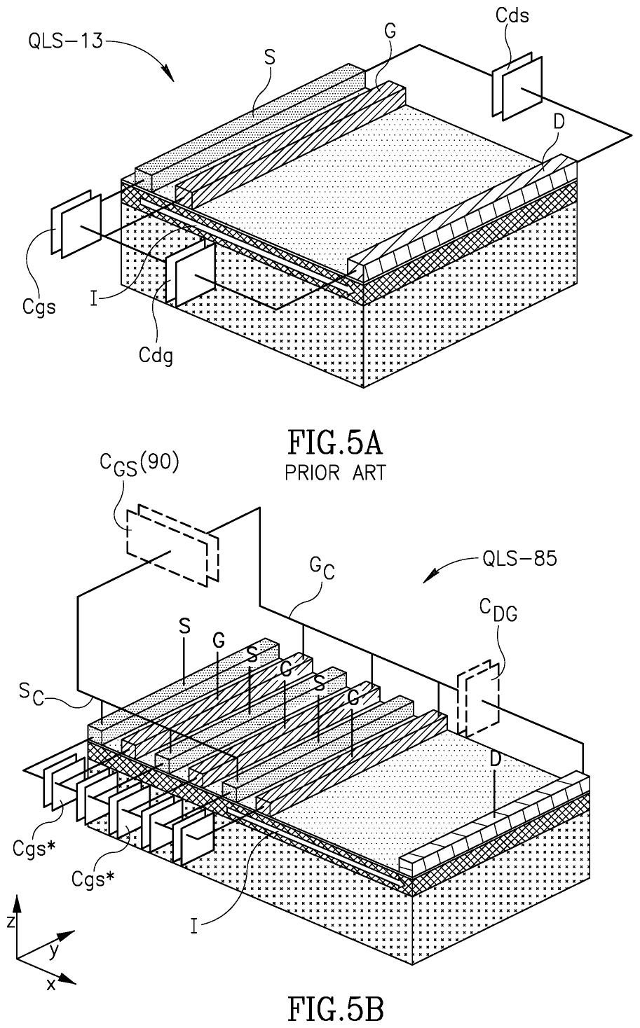

FIGS. 5A and 5B schematically illustrate differences between a prior art transistor such as QLS-13 comprised in half bridge 10 and a transistor QLS-85 in accordance with an embodiment of the disclosure that may be comprised in half bridge 80 of FIG. 4 to moderate or prevent shoot-through currents in a half bridge.

Conventional transistor QLS-13 shown in FIG. 5A has source and drain regions overlaid respectively by source and gate electrodes labeled S and D and a gate region overlaid by a gate electrode G for controlling resistance, and current I indicated by a block arrow, between the source and the drain regions. For convenience of presentation, in FIG. 5A and FIG. 5B source, drain, and gate regions are not explicitly shown or distinguished from their respective electrodes and are referenced by the same labels S, D, and G that label the electrodes. Parasitic capacitances Cgs and Cdg respectively couple source region S to gate region G and gate region G to drain region D. A parasitic capacitance Cds couples drain region D to source region S.

Transistor QLS-85 on the other hand, as shown in FIG. 5B, is configured having a plurality of, optionally three, source regions S interleaved with, three gate regions G operable to control resistance and thereby current between source regions S to a same drain region D, in accordance with an embodiment of the disclosure. Each source region S is coupled to an adjacent gate region G by an internal parasitic capacitance Cgs*. The three source regions are connected electrically in parallel to form a compound source S_{C}, and the three gate regions are connected electrically in parallel to form a compound gate G_{C}. For the configuration shown in FIG. 5B there are 5 internal parasitic capacitances Cgs* in parallel between compound source S_{C} and compound gate G_{C}. Assuming all the parasitic capacitances have substantially a same magnitude, a total internal, built-in, parasitic capacitance schematically represented by a dashed capacitor C_{GS}, bridges compound source S_{C} and compound gate G_{C} and provides transistor QLS-85 with a relatively large built-in parasitic capacitance equal to about 5×Cgs*. The large internal parasitic capacitance shunts internal impedances of the transistor and operates to provide half bridge 80 with enhanced protection against shoot-through.

It is noted that in general for N gate source pairs in QLS-85 as schematically shown in FIG. 5B, the built-in parasitic capacitance C_{GS} may be approximated as equal to about (2N−1)Cgs*. Magnitude of C_{GS} may be adjusted as required for a given circuit and ambient stray capacitance and/or inductance to which the circuit may be exposed by selecting a suitable number N of gate-source pairs. Magnitude of built-in capacitance of C_{GS} may also be adjusted by forming gate-source pairs having different sizes and/or different distances between gate regions and source regions of different gate-source pairs, or distances between different gate-source pairs. For example, assuming that a first gate-source pair has a lateral extent Lgs substantially parallel to the y-axis of the coordinate system shown in FIG. 5B, and an additional N′ gate source pairs having, optionally a same y-axis lateral extent αLgs, where 0≤α≤1, C_{GS} may be approximated by an expression C_{GS}˜ Cgs*+2 N′αCgs*. In the last expression it is also assumed that distances along the x-axis between all gate regions and their respective adjacent source regions are the same for all gate regions.

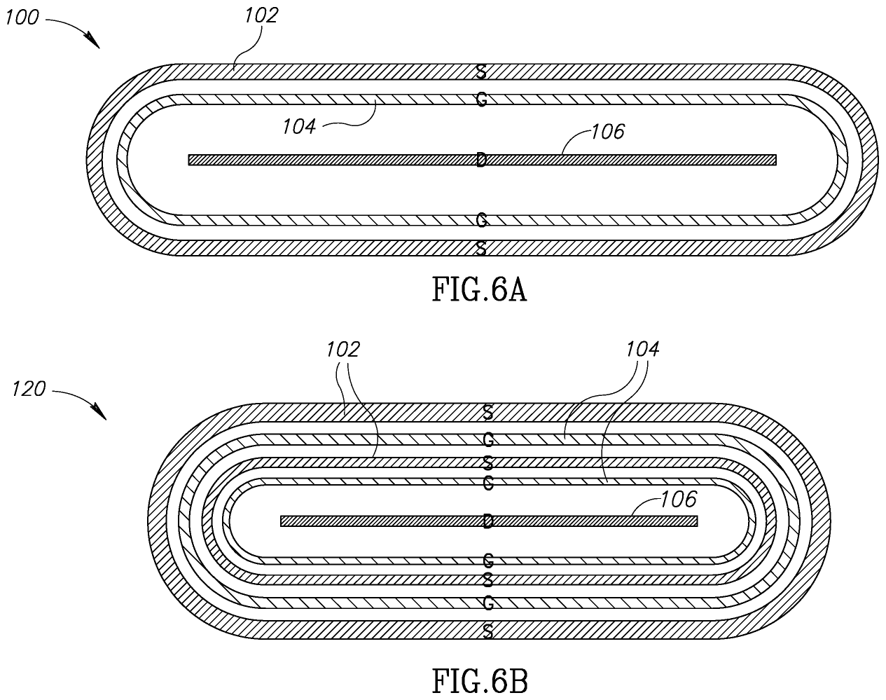

FIGS. 6A and 6B schematically show top views of transistors 100 and 120 respectively that have relatively large built-in parasitic capacitance and may advantageously function as low side switch transistors in a half bridge, in accordance with an embodiment of the disclosure. Transistors 100 and 120 are characterized by source-gate pairs having substantially round rectangular shapes that, optionally completely, surround a drain of the transistor. Transistor 100 shown in FIG. 6A comprises a single drain 106 surrounded by a source-gate pair comprising a surround source 102 and a surround gate 104 nested inside surround source 102. Ignoring the rounded ends of the surround 102 and a surround gate 104 and assuming that one side of the surround source-gate pair has a “one side” stray capacitance equal to about Cgs*, a total built-in parasitic capacitance C_{GS} of transistor 100 may be estimated to be equal to about 2Cgs*.

Similarly, transistor 120 shown in FIG. 6B comprises 2 surround source-gate pairs and may be estimated to have a total parasitic capacitance C_{GS} equal to about (2×3)Cgs*. In general a transistor having N surround source-gate pairs surrounding a single drain in accordance with an embodiment of the disclosure may be estimated to have a built-in stray capacitance C_{GS}=2(2N−1)Cgs*. The surround feature of a surround source-gate pair in general operates to about double a built-in stray capacitance of a source-gate pair similar in structure and geometry to a single side of a surround source-gate pair.

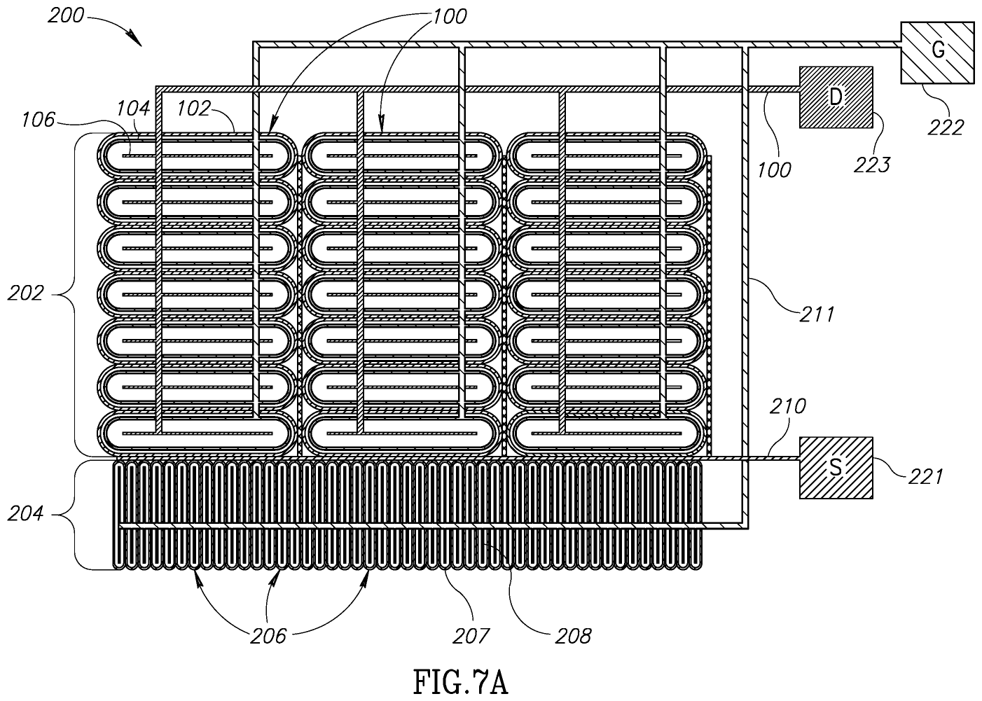

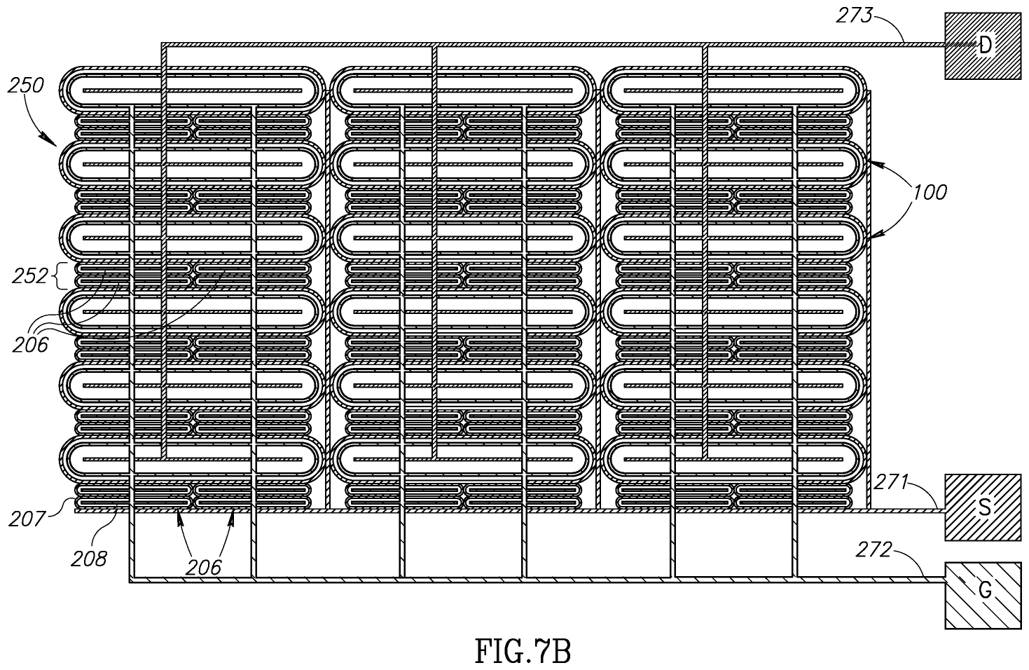

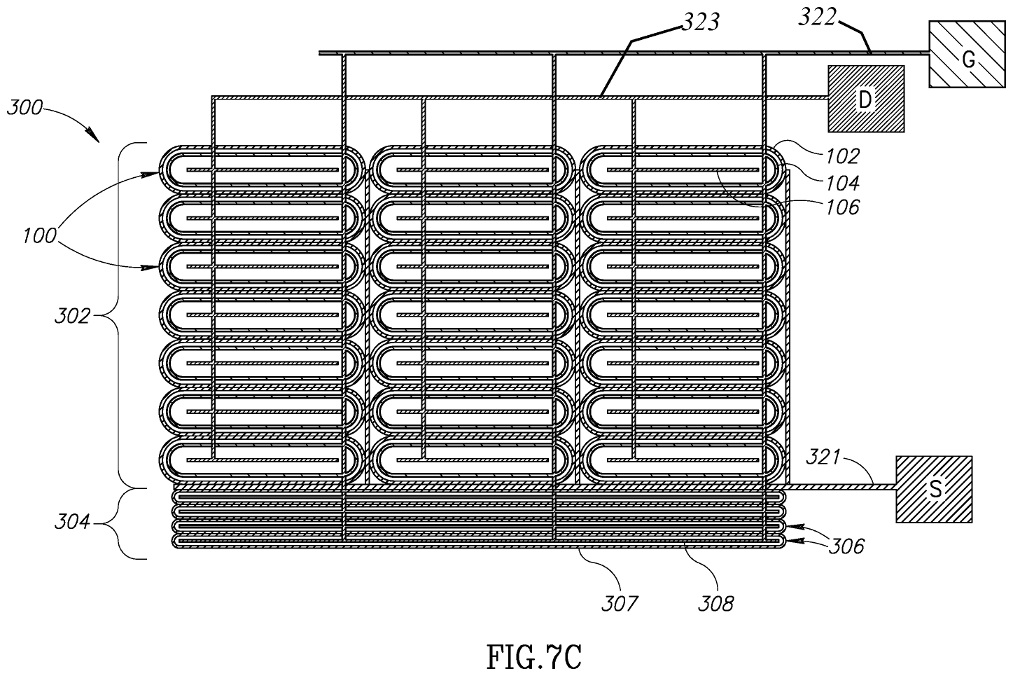

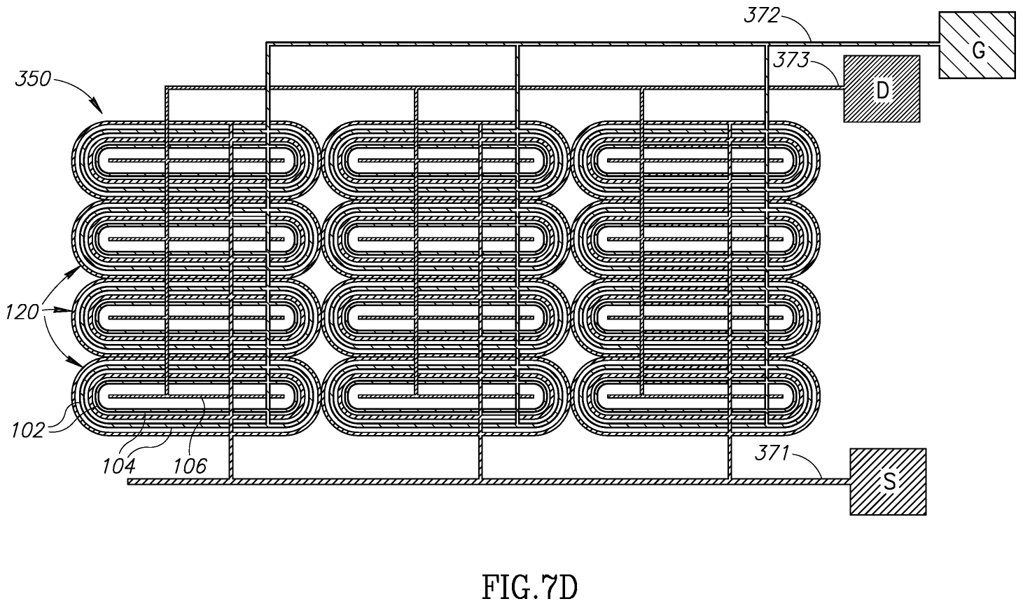

FIGS. 7A-7D show schematic views of compound switching devices, also referred to as a switching die, comprising a plurality of transistors 100 (FIG. 6A) or 120 (FIG. 6B), in accordance with embodiments of the disclosure.

FIG. 7A shows a schematic of a switching die 200 comprising an array 202 having a plurality of transistors 100. In addition to array 202 switching die 200 comprises an array 204 of built-in capacitors 206 along a lower side of array 202, each capacitor 206 having a center electrode 208 surrounded by a surround electrode 207. A conducting trace 221 connects surround electrodes 207 of all capacitors 206 and sources 102 of all transistors 100 in parallel. A conducting trace 222 connects center electrodes 208 of all capacitors 206 and gates 104 of all transistors 100 in parallel. A conducting trace 223 connects drains 106 of all transistors 100 in parallel.

FIG. 7B shows a schematic of a switching die 250 comprising a plurality of transistors 100 interleaved with arrays 252 of built-in capacitors 206. A conducting trace 271 connects surround electrodes 207 of all capacitors 206 and sources 102 of all transistors 100 in parallel. A conducting trace 272 connects center electrodes 208 of all capacitors 206 and gates 104 of all transistors 100 in parallel. A conducting trace 273 connects drains 106 of all transistors 100 in parallel.

FIG. 7C shows a schematic of a switching die 300 comprising an array 302 having a plurality of transistors 100. In addition to array 302, switching die 200 comprises an array 304 of built-in capacitors 306 along a lower side of array 302, each capacitor 306 having a center electrode 308 surrounded by a surround electrode 307 and extending a full length along the lower side. A conducting trace 321 connects surround electrodes 307 of all capacitors 306 and sources 102 of all transistors 100 in parallel. A conducting trace 322 connects center electrodes 308 of all capacitors 306 and gates 104 of all transistors 100 in parallel. A conducting trace 323 connects drains 306 of all transistors 100 in parallel.

FIG. 7D shows a schematic of a switching die 350 comprising a plurality of transistors 120 (FIG. 6B) in accordance with an embodiment of the disclosure. A conducting trace 371 sources 102 of all transistors 120 in parallel. A conducting trace gates 104 of all transistors 120 in parallel. A conducting trace 373 connects drains 106 of all transistors 120 in parallel.

Descriptions of embodiments of the invention in the present application are provided by way of example and are not intended to limit the scope of the invention. The described embodiments comprise different features, not all of which are required in all embodiments of the invention. Some embodiments utilize only some of the features or possible combinations of the features. Variations of embodiments of the invention that are described, and embodiments of the invention comprising different combinations of features noted in the described embodiments, will occur to persons of the art. The scope of the invention is limited only by the claims.

1. A lateral semiconductor transistor comprising:
a drain electrode located over a drain region;
a plurality of source electrodes, each source electrode overlaying a source region; and
a plurality of gate electrodes interleaved and alternating with the source electrodes;
wherein each gate electrode of the plurality of gate electrodes is located between a source electrode of the plurality of source electrodes and the drain electrode.

2. The semiconductor transistor according to claim 1 wherein all the source electrodes are electrically connected together.

3. The semiconductor transistor according to claim 2 wherein all the gate electrodes are electrically connected together.

4. The semiconductor transistor according to claim 1 wherein a number of the plurality of gate electrodes is equal to a number of the plurality of source electrodes to form a plurality of gate-source pairs, each gate-source pair comprising a gate electrode and an adjacent source electrode on a far side of the gate electrode relative to the drain electrode.

5. The semiconductor transistor according to claim 4 wherein a total built-in internal gate-source capacitance C_{GS} of the transistor is an increasing function of a number of the gate-source pairs.

6. The semiconductor transistor according to claim 5 wherein at least two gate-source pairs have different lateral extents.

7. The semiconductor transistor according to claim 5 wherein for at least two gate-source pairs of the plurality of gate-source pairs, distances between source electrodes and gate electrodes are different.

8. The semiconductor transistor according to claim 5 wherein the distances between the gate electrodes and the source electrodes are the same for all the gate-source pairs of the plurality of gate-source pairs.

9. The semiconductor transistor according to claim 8 wherein the gate-source pairs are equally spaced.

10. The semiconductor transistor according to claim 9 wherein if N is equal to the number of gate-source pairs and capacitance between a gate electrode and a source electrode is represented by C_{gs}* then C_{GS} is equal to about (2N−1)Cgs*

11. The semiconductor transistor according to claim 1, wherein the source electrodes of the plurality of source electrodes are surround source electrodes completely surrounding the drain electrode.

12. The semiconductor transistor according to claim 11 wherein the gate electrodes of the plurality of gate electrodes are surround gate electrodes completely surrounding the drain electrode.

13. A lateral semiconductor transistor comprising:
a drain electrode;
a plurality of surround source electrodes each completely surrounding the drain electrode; and
a plurality of surround gate electrodes interleaved and alternating with the surround source electrodes, each surround gate electrode completely surrounding the drain electrode and lying within an area bounded by a surround source electrode of the plurality of surround source electrodes.

14. A semiconductor switching die comprising a plurality of transistors according to claim 1.

15. The semiconductor switching die according to claim 14 wherein the source electrodes of the plurality of transistors are electrically connected in parallel.

16. The semiconductor switching die according to claim 14 wherein the gate electrodes of the plurality of transistors are electrically connected in parallel.

17. The semiconductor switching die according to claim 14 wherein the drain electrodes of the plurality of transistors are electrically connected in parallel.

18. A half bridge having a low side switch comprising a semiconductor transistor according to claim 1.
